(19) United States
(12) Patent Application Publication
(10) Pub. No.: US 2026/0352241 A1
(43) Pub. Date: Nov. 5, 2026

(54) RADIO FREQUENCY (RF) MODULATOR CONTROL SYSTEMS AND METHODS

(71) Applicant: KEYSIGHT TECHNOLOGIES, INC., SANTA ROSA, CA (US)

(72) Inventors: Garrett Foltz, Santa Rosa, CA (US); Sophia Elia, Santa Rosa, CA (US)

(21) Appl. No.: 19/553,269

(22) Filed: Feb. 28, 2026

Related U.S. Application Data
(60) Provisional application No. 63/797,688, filed on Apr. 30, 2025.

(51) Int. Cl. H04B 1/04; H03K 19/177

(52) U.S. Cl. CPC H04B 1/04; H03K 19/177; H04B 2001/0491

(57) ABSTRACT

A system for linearizing RF modulators includes a plurality of RF modulators connected in series, a field-programmable gate array (FPGA) configured to control the RF modulators, and a piecewise linear mapping module implemented in the FPGA, the piecewise linear mapping module configured to divide an operating range of the RF modulators into multiple power regions, and apply different linearization parameters to each power region to compensate for a non-linear behavior of the RF modulators.

The present application claims priority under 35 U.S.C. § 119(e) and under 37 C.F.R. § 1.78(a) to commonly owned U.S. Provisional Application No. 63/797,688, filed on Apr. 30, 2025. The entire disclosure of U.S. Provisional Application No. 63/797,688 is specifically incorporated herein by reference in its entirety.

### FIELD

The present disclosure relates to radio frequency (RF) modulator control systems, and more particularly to a method and apparatus for linearizing and optimally controlling multiple RF modulators using piecewise linear mapping and an FPGA-based scheduling algorithm.

### BACKGROUND

Radio frequency (RF) modulators are essential components in many modern communication systems, including wireless transmitters, radar systems, and test equipment. These devices control the amplitude of RF signals, allowing for precise adjustment of output power levels across a wide dynamic range. However, achieving accurate and linear control of RF modulators presents several challenges.

One significant challenge is the inherent non-linearity of many RF modulator components, particularly PIN diodes commonly used in variable attenuators. The relationship between control voltage and attenuation is often non-linear, leading to inaccuracies in output power control. This non-linearity can result in distortion of the modulated signal and reduced overall system performance.

Another challenge is maintaining consistent performance across different operating conditions. Factors such as temperature variations, frequency dependencies, and component aging can all affect the behavior of RF modulators. These variations can lead to inconsistencies in output power levels and introduce errors in signal modulation.

Traditional approaches to addressing these challenges have relied on analog compensation techniques, such as using exponential function generators to linearize the control response. However, these analog methods often have limitations in terms of accuracy, flexibility, and adaptability to changing conditions.

The increasing availability of high-performance digital components, such as field-programmable gate arrays (FPGAs), has opened up new possibilities for implementing more sophisticated control and linearization techniques. Digital approaches offer the potential for improved accuracy, adaptability, and integration with other system functions.

Optimizing the performance of RF modulator systems also involves careful consideration of noise characteristics and harmonic distortion. Balancing these factors across the full operating range of the system can be complex, particularly when multiple modulator stages are used in series.

### SUMMARY

According to an aspect of the inventive concepts, a system for linearizing RF modulators is provided. The system includes a plurality of RF modulators connected in series, a field-programmable gate array (FPGA) configured to control the RF modulators, and a piecewise linear mapping module implemented in the FPGA, the piecewise linear mapping module configured to divide an operating range of the RF modulators into multiple power regions, and apply different linearization parameters to each power region to compensate for a non-linear behavior of the RF modulators.

The plurality of RF modulators may include at least three RF modulators connected in series. The at least three RF modulators may include an input modulator, at least one middle modulator, and an output modulator. The multiple power regions may include a lowermost power region, at least one middle power region, and a higher most power region. The piecewise linear mapping module may be further configured to apply different linearization parameters to each of the input modulator, the at least one middle modulator, and the output modulator within each power region. The piecewise linear mapping module may be further configured to sequence activation of the input modulator, the at least one middle modulator, and output modulator to balance noise and distortion performance across the multiple power regions, and the piecewise linear mapping module may utilize lookup tables to store the linearization parameters for each modulator in each power region.

The system may include a normalization process that utilizes the full bit depth piecewise linear map of a given the power range.

According to another aspect of the inventive concepts, a method for linearizing RF modulators is provided. The method includes dividing an operating range of a plurality of series-connected RF modulators into multiple power regions, determining distinct linearization parameters for each power region, and applying the distinct linearization parameters to the RF modulators using a field-programmable gate array (FPGA) to compensate for a non-linear behavior of the RF modulators across the operating range.

Determining linearization parameters may include calibrating each RF modulator individually to characterize its non-linear behavior across the operating range.

The method may further include storing the linearization parameters in lookup tables implemented in the FPGA.

According to yet another aspect of the inventive concepts, a non-transitory computer-readable medium is provided that stores instructions that, when executed by a processor, cause the processor to perform the above summarized method for linearizing RF modulators.

### BRIEF DESCRIPTION OF THE DRAWINGS

The above and other aspects and features of the inventive concepts will become readily apparent from the detailed description that follows, with reference to the accompanying drawings, in which:

FIG. 1 is simplified circuit diagram of a modulator gain system 100 according to embodiments of the inventive concepts.

FIG. 2 is a table illustrating registers for programming the FPGA modular compensation block according to an example embodiment;

FIG. 3 depicts an example of pseudo code illustrating the manner in which the modulator schedule breaks into regions according to an example embodiment;

FIG. 4 is a graphical representation of a modulator linearization schedule according to an example embodiment;

FIG. 5 is a table describing DAC values and switch point characteristics associated with each of a DAC values according to an example embodiment.

FIGS. 6 and 7 are sweep diagrams of one modulator;

FIGS. 8 and 9 are measured output power and power error graphs for reference in describing calibration results of the inventors; and

FIG. 10 is a high-level and simplified block diagram of a computing system according to embodiments of the inventive concepts.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

The drawings may in some cases focus on structural features of embodiments of the inventive concepts. However, the drawings may not be drawn to scale, and relative dimensions of different structural elements may differ from those depicted in the drawings. Further, throughout the drawings, like reference numbers refer to the same or similar elements.

As is traditional in the field of the inventive concepts, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

As will be explained below, embodiments of the inventive concepts sets the voltage of PIN diode modulators in an RF chain via a linearization algorithm and optimal noise schedule. In some embodiments, piecewise linear mapping of power to DAC values is utilized to linearize the modulators via FPGA. This allows for precise linearization that is calibrated vs. the frequency response of the modulators. The inventive concepts offer advantages over prior solutions which use relatively less accurate and temperature variable analog “exponentiator” circuits to linearize the RF modulators. Additionally, prior solutions are devoid of any attempt to sequence the modulators to optimally balance noise, thus causing degradation of the overall noise figure of the chain.

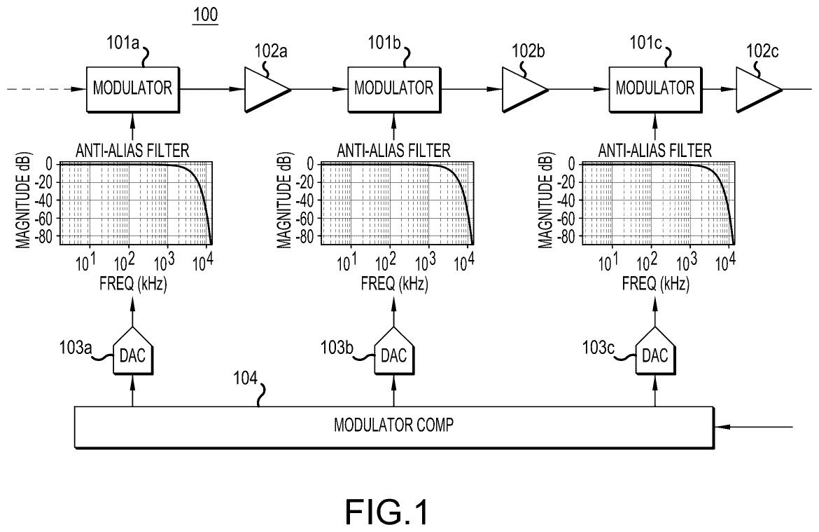

FIG. 1 is simplified circuit diagram of a modulator gain system 100 according to embodiments of the inventive concepts. For convenience of the description, the illustrated system is a 3 modulator gain system, but the inventive concepts are not limited by the number of modulators in the RF chain of the system. Specifically, the inventive concepts encompass modulator gain systems including two (2) or more modulators in the RF chain.

Referring to FIG. 1, modulator gain system includes PIN modulators 101a, 101b and 101c connected in a cascade configuration to form an RF chain. Namely, the output of RF modulator 101a forms the input of RF modulator 101b, and the output of RF modulator 101b forms the input of RF modulator 101c. In embodiments, the RF modulators 101a, 101b and 101c are PIN diode modulators.

Reference numbers 102a, 102b and 102c of FIG. 1 denote non-linear, time variant systems of the RF chain. Each of the systems can include components (e.g., amplifiers, signal traces, and so on) which introduce non-linearities in the RF chain.

The system 100 further includes a field-programmable gate array (FPGA) modulator compensation block 104 configured to control the RF modulators 101a, 101b and 101c. In embodiments, this is achieved through digital-to-analog convertors (DACs) 103a, 103b and 103c. As will be explained below, a piecewise linear mapping module is implemented in the FPGA 104. Here, the piecewise linear mapping module is configured to divide an operating range of the RF modulators 101a, 101b and 101c into multiple power regions, and apply different linearization parameters to each power region to compensate for a non-linear behavior of the RF modulators. These linearization parameters are represented by characters A, B and C in FIG. 1. In embodiments, in order to find the optimal drive levels, a sequencing scheme is used to optimally balance the tradeoff between the RF chain kTBR noise floor and distortion in the form of harmonics.

As mentioned above, the current embodiment illustrates 3 modulators in the RF chain for purposes of description. In the description that follows, these modulators will be referred to as an input (IN) modulator (i.e., modulator 101a), a middle (MID) modulator (i.e., modulator 101b) and an output (OUT) modulator (i.e., modulator 101c).

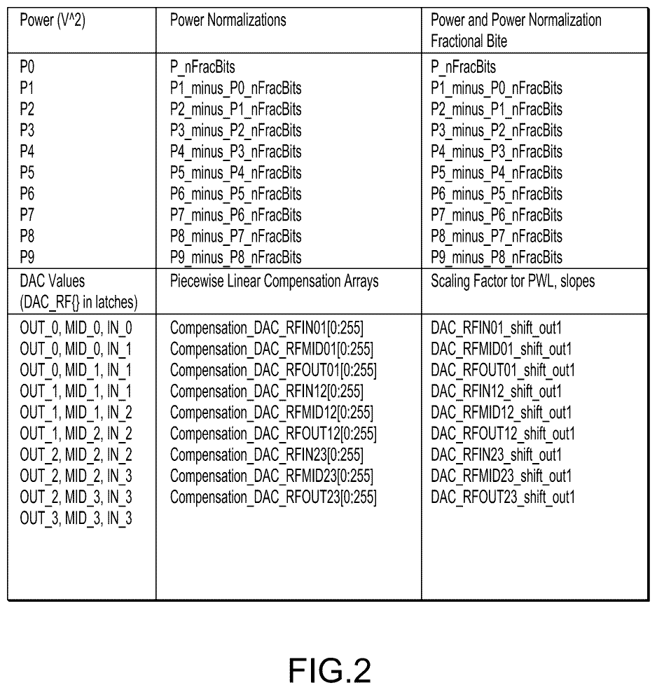

Attention is directed to the table illustrated in FIG. 2, illustrating registers for programming the FPGA modular compensation block 104. For a given mode, band and frequency there is a unique set of parameters as shown in FIG. 2. In the example of FIG. 2 there are ten power levels P0 to P9. As shown, power normalizations are the inverse of the difference between adjacent power levels. Also shown in FIG. 2 are registers for power and power normalization fractional bits, DAC values, piecewise linear (PWL) compensation arrays, and scaling factors for PWL slops.

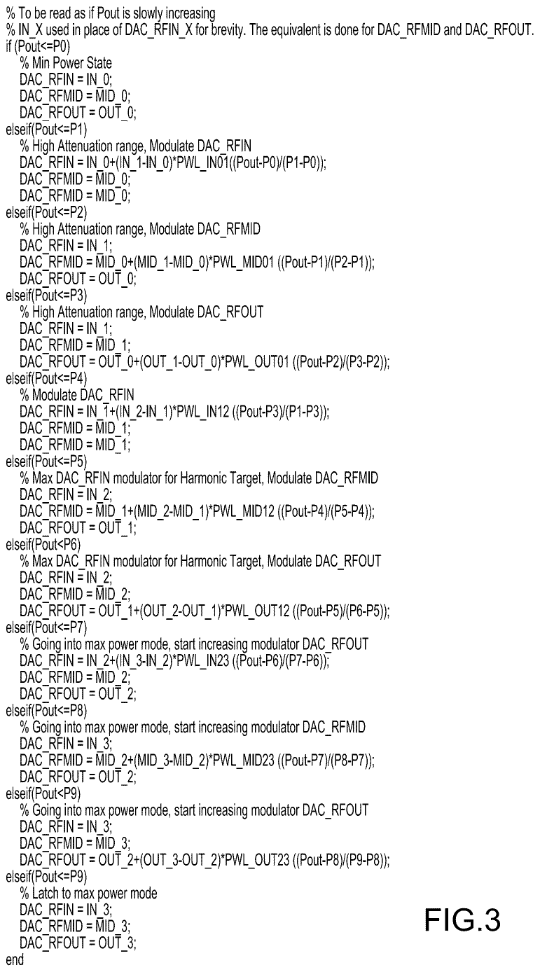

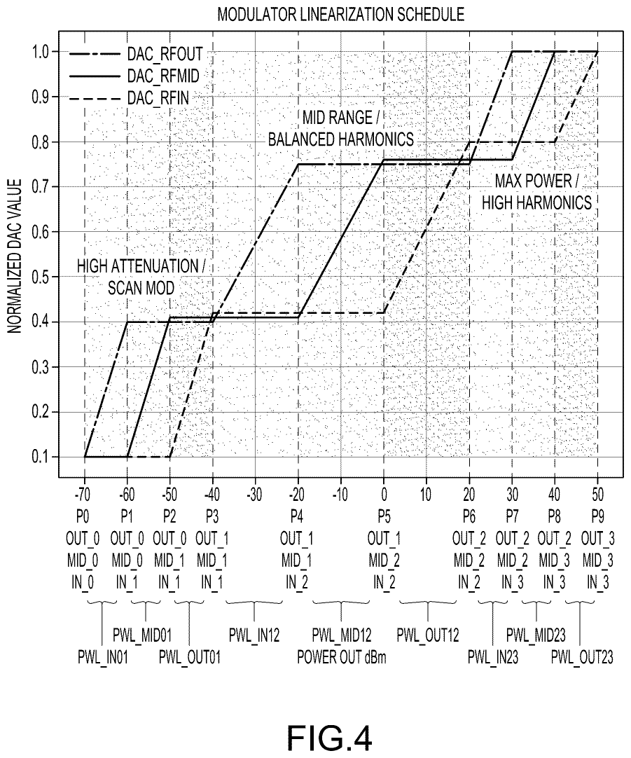

FIG. 3 presents an example of pseudo code illustrating the manner in which the modulator schedule breaks into regions. As shown, the region being coded is determined by comparing an output power Pout with each of the power levels P0 through P9. As also shown, within each region, DAC values DAC_RFIN, DAC_RFMID and DAC_RFOUT are set. This will be explained in greater detail below with reference to FIG. 4.

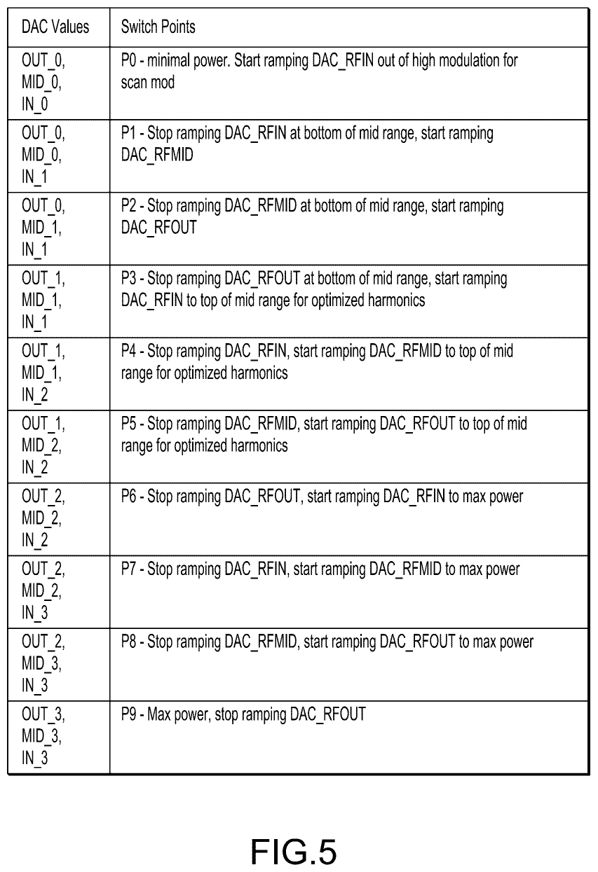

FIG. 4 illustrates a graphical representation of a modulator linearization schedule according to an example embodiment, and FIG. 5 is a table describing DAC values and switch point characteristics associated with each of the DAC values. As before, the example of FIGS. 4 and 5 assume a 3 modulator gain system. Again, however, the inventive concepts are not limited by the number of modulators in the RF chain.

Referring to FIG. 4, the x-axis shows increasing power levels P0 through P9, and the y-axis shows normalized DAC values for each of DAC_RFIN, DAC_RFMID and DAC_RFOUT. It can be seen that three power regions are generally defined a high attenuation/scan mod region, a mid range/balance harmonics region, and a max power/high harmonics region.

Referring collective to FIGS. 4 and 5, a process for optimally determining the DAC values and power switch points is described next.

### Setting P0, P1, P2 and P3:

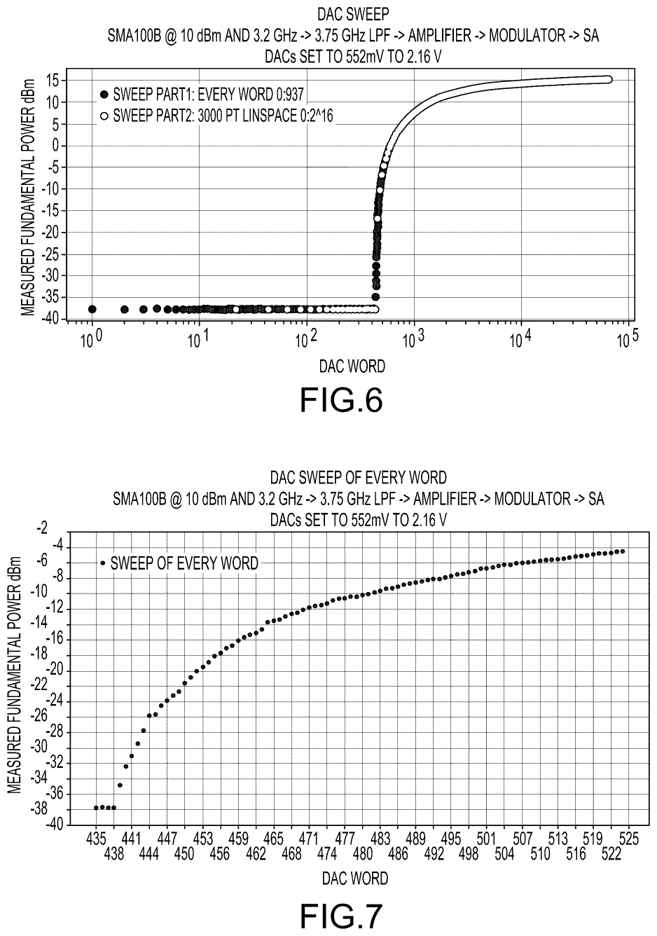

Consistent with the previous description, assume the modulators are configured DAC_RFIN→DAC_RFMID→DAC_RFOUT where DAC_RFOUT is the modulator closest to the output. At least one flavor of the modulator has a characteristic curve with a very steep gain after the turn on point and little resolution in terms of dB/DAC word around that point. To mitigate this, the schedule is broken into the three sections mentioned previously.
1. High attenuation/low power range for scan mod.
2. A mid power range with optimized harmonics. It is desired to achieve at least 30 dB of range per DAC. Therefore, the low end of the mid power range should be at least 30 dB down from max power for each DAC and should also be clear of the highly variable turn on point of the modulator. Referring to FIGS. 6 and 7, the low end of the mid range could be chosen between −20 and −15 dBm.
3. A high power range where the harmonics are no longer optimized.

FIGS. 6 and 7 are sweep diagrams of one modulator. Referring to these diagrams, P0 is picked slightly after the turn on point for each modulator. P1, P2, and P3 are picked so that each modulator is at least 30 dB down from max power, the highly variable range of the modulator is avoided, and the harmonics are low enough that they are not contributing to the harmonic measurement.

### Setting P4-P9:

It is necessary to balance harmonic performance during characterization, but it remains to be seen if balancing must also be done for all instruments during normal characterization.

Given a second harmonic specification of P_{OUT} in dBc, calculate the target harmonic levels for each stage of the optimization. This is done by assuming equal, in-phase contribution to the harmonic from each DAC. Below are the target dBc levels for DAC B and C:

$${P}_{IN} d B c = 10 {log}_{10} ( \frac{1}{3} ( {10}^{\frac{{P}_{OUT}}{10}} ) )$$

$${P}_{MID} d B c = 10 {log}_{10} ( \frac{2}{3} ( {10}^{\frac{{P}_{OUT}}{10}} ) )$$

An example balancing algorithm is as follows:
1. Determine P0, P1, P2, P3 as above.
2. Setting RFOUT, RFMID, and RFIN DACs to the value X, find X such that the RF output measures −10 dBm. The assumption here is that −10 dBm is low enough that none of the DACs should be contributing to the harmonic measurement. Note the second harmonic dBc value.
3. Leaving DAC_RFOUT fixed at X, lower the attenuation of DAC_RFIN while raising the attenuation of DAC_RFMID so that the output remains constant at −10 dBm. Continue until the second harmonic reaches PIN. Record the attenuation setting of DAC_RFIN as value DAC_RFIN_2. Record the output power as P4.
4. With DAC_RFIN set to DAC_RFIN_2, lower the attenuation of DAC_RFMID while raising the attenuation of DAC_RFOUT so that the output remains constant at −10 dBm. Continue until the second harmonic reaches P_{MID}. Record the attenuation setting of DAC_RFMID as value DAC_RFMID_2. Record the output power as P5.
5. With DAC_RFIN set to DAC_RFIN_2 and DAC_RFMID set to DAC_RFMID_2, increase DAC_RFOUT until reaching the desired value for High Vernier. Note the second harmonic level at this setting and make sure it is not larger than P_{A}. If it is higher, a lower High Vernier value must be chosen. Record the attenuation setting of DAC_RFOUT as DAC_RFOUT_2. Record the output power as P6.
6 Leaving DAC_RFOUT and RFMID fixed, decrease attenuation in DAC_RFIN until it is at a minimum (or close to minimum). Record the output power as P7. Record the attenuation setting of DAC_RFIN as DAC_RFIN_3.
7. Leaving DAC_RFIN and RFOUT fixed, decrease attenuation in DAC_RFMID until it is at a minimum (or close to minimum). Record the output as power P8. Record the attenuation setting of DAC_RFMID as DAC_RFMID_3.
8. Leaving DAC_RFIN and RFMID fixed, decrease attenuation in DAC_RFOUT until it is at a minimum (or close to minimum). Record the output as power P9. Record the attenuation setting of DAC_RFOUT as DAC_RFOUT_3.

Next, a modulator linearization procedure according to embodiments of the inventive concepts will be described.

### Modulator Linearization Procedure

When the optimal DAC settings are found as described above, the output power vs DAC settings relationship must be determined for the FPGA to compute the linearization. This is a segmented approach to linearizing unique power ranges per modulator. As such, first consider the power range between P0 and P1:

$$DAC\_RFIN = RFIN\_ 0 + ( RFIN\_ 1 - RFIN\_ 0 ) {PWL}_{IN 01} ( \frac{{P}_{out} - P 0}{P 1 - P 0} )$$

$$DAC\_RFMID = B 0$$

$$DAC\_RFOUT = A 0$$

By referencing the pseudo-code one must collect a set of data from DAC_RFIN_0 to DAC_RFIN_1 to fill the PWL_IN01 calibration arrays, an example of which is shown below:

| DAC_RFIN Values | Power Meter (dBm) |
|---|---|
| 164 (RFIN_0) | −30.1376009 (P0) |
| 164 | −30.1472796 |
| 163 | −30.0635653 |
| . . . | . . . |
| 513 | −12.9302427 |
| 517 | −12.8884016 |
| 522 | −12.8313799 |
| . . . | . . . |
| 1025 | −9.01601888 |
| 1034 | −8.97536992 |
| 1042 | −8.92816347 |
| . . . | . . . |
| 1537 | −6.94636314 |
| 1550 | −6.90604945 |
| 1564 (RFIN_1) | −6.86360758 P(1) |

The first step is to normalize the DAC value data to be from [0:1]. Let y_in be a sampled DAC_RFIN word. The normalized DAC word y̅_̅i̅n̅ is calculated as,

$$\overline{y\_in} = \frac{y\_in - RFIN 0}{RFIN 1 - RFIN 0} .$$

The power meter readings are converted from dBm to Volts\hat{ }2, and then also normalized such that

$$\overline{x\_meas} = \frac{x\_meas - P 0}{P 1 - P 0} .$$

In the piecewise linear map PWL_IN01, one can set y̅_̅i̅n̅=PWL_{IN01}(x̅_̅m̅e̅a̅s̅).

The normalized values give a new data mapping as shown below:

| DAC_RFIN Normalized | Power Meter Normalized |
|---|---|
| 0 | 0 |
| 0.0007 | 1.67E−05 |
| 0.1 | 8.13E−05 |
| . . . | |
| 0.249 | 0.243806 |
| 0.253 | 0.246212 |
| 0.256 | 0.249528 |
| . . . | |
| 0.615 | 0.607351 |
| 0.622 | 0.613107 |
| 0.627 | 0.619859 |
| . . . | |
| 0.98 | 0.981036 |
| 0.99 | 0.990229 |
| 1.0 | 1 |

Now to do the “inverse” function to linearize the data, one must set the normalized power reading as the independent variable.

In the example of the current embodiment, referring to the table that follows, the upper 8-bits of the power data will be used as the table lookups and the remaining bits will be the fractional bits.

| DAC_RFIN01 | Power Meter | Power Meter |
|---|---|---|
| Normalized | Normalized | Normalized |
| Binary | Binary Upper | Binary Fractional |
| 0 | 0 | 0 |
| 45.8752 | 0 | 4483 |
| 6553.6 | 0 | 21824 |
| . . . | | |
| 16318.464 | 62 | 434463 |
| 16580.608 | 63 | 31742 |
| 16777.216 | 63 | 921874 |
| . . . | | |
| 40304.64 | 155 | 505263 |
| 40763.392 | 156 | 1001801 |
| 41091.072 | 158 | 717125 |
| . . . | | |
| 64225.28 | 251 | 152270 |
| 64880.64 | 253 | 522845 |
| 65536 | 255 | 0 |

From here one can do the standard piecewise linear segmented fitting routines. To complete the calibration arrays, this process is repeated for PWL_{MID01}, PWL_{OUT01}, PWL_{IN12}, etc.

Once the regression is done, the slopes and offsets that are output will be double precision and must be scaled into the appropriate data type for the FPGA.

The FPGA data types for offset is Sfix16_15en number, but the m value is a sfix16_45en number. So the slope must be scaled by 2\hat{ }30 and the offset must be scaled by 2\hat{ }−1.

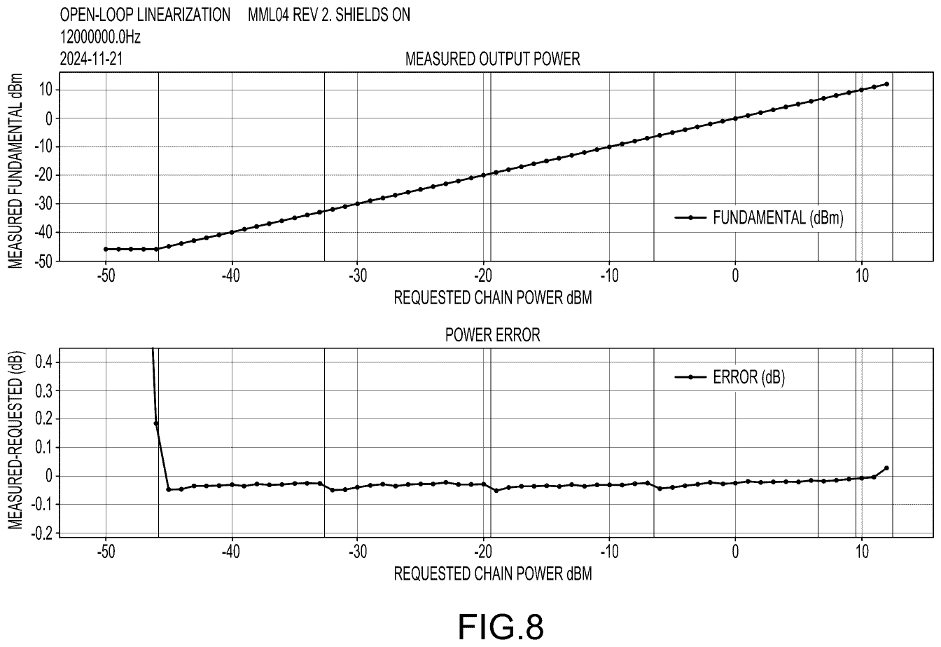

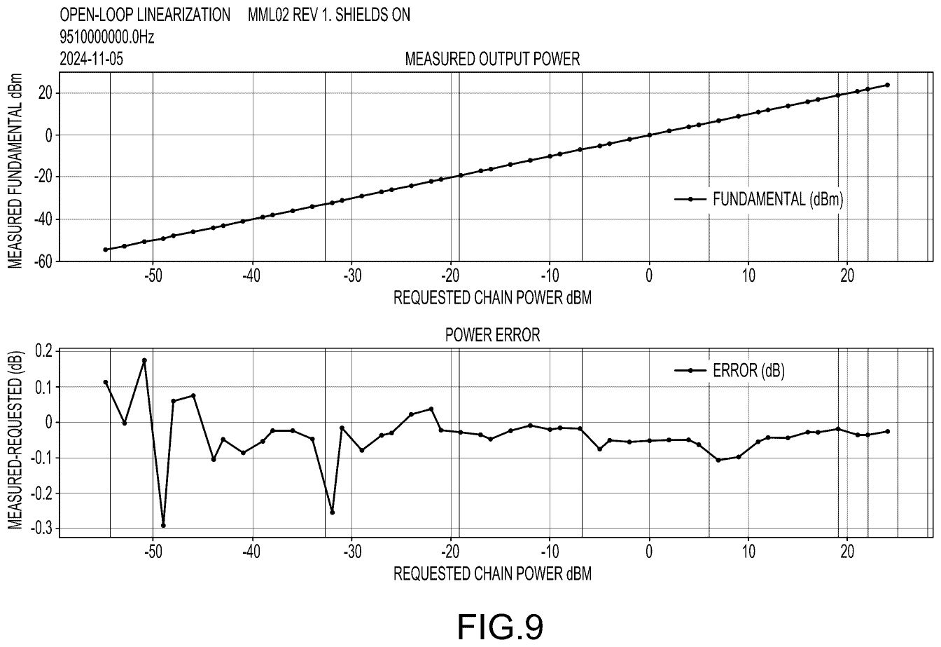

With reference to the measured output power and power error graphs of FIGS. 8 and 9, calibration results of the inventors will be described next. In particular, the modulator linearization scheme of the inventive concepts has been tested on 2 types of modulators.

FIG. 8 shows a linearization in the low band path at 12 MHz, with 2 modulators present in the RF chain. The vertical gray lines indicate regions of the schedule. The calibration was done over a 48 dB span, from −46 dBm to 12 dBm. The power after calibration is accurate well within 0.1 dB.

FIG. 9 shows a linearization in high band path at 9.51 GHz, with 3 modulators present in the RF chain. The calibration is accurate within 0.3 dB over a 80 dB range.

The description will now turn to data types/representations in embodiments of the inventive concepts.

Representation of the schedule powers P₀, P1, . . . , P9:

The schedule powers may each be represented with 32 bits including P_nFracBits fractional bits, and (32−P_nFracBits) integer bits. To choose an appropriate value for P_nFracBits, a power range from −50 dBm to 35 dBm was considered. Recall that Power in

$${Volts}^{2} = \frac{50}{1000} {10}^{Power in dBm / 10} .$$

### Thus:

35 dBm=158.113V²

log₂(158.113)=7.3

This implies that to represent 35 dBm as a 32-bit word, one needs 8 integer bits and 24 fractional bits.

Choosing to keep as many fractional bits as possible, one may set P_nFracBits=24.

For the lower end of the power spectrum:

−50 dBm=5*10⁻⁷V²

log₂(5*10⁻⁷)=−20.93

This implies that with 24 fractional bits, −50 dBm receives 4 bits of resolution.

In order to store the powers in the schedule, multiply the Volts\hat{ }2 power by 2²⁴=2^{P}^{_{nFracBits}} and round to the nearest integer:

schedule·Px=round(2^{P}^{_{nFracBits}}(Px in Volts²)), for x∈{0,1, . . . ,6}.

This represents Px as an integer value so the binary point does not need to be carried around, but implicitly, one knows that it has been multiplied by 2^{P_nFracBits}.

Representation of Power Normalizations

$$\frac{1}{{P}_{1} - {P}_{0}} , … , \frac{1}{{P}_{9} - {P}_{8}} :$$

The power normalizations are represented with 32 bits. One can estimate the range of values as a range from

$$\frac{1}{{P}_{9}} to \frac{1}{{P}_{0}} .$$

$$\frac{1}{{P}_{9}} = \frac{1}{158.11 {V}^{2}} = 0.006324$$

$$log\_ 2 ( 0.006324 ) = - 7.3$$

This is as expected; above we found that log₂(158.11)=7.3. By the same logic, 21 integer bits are needed to represent

$$\frac{1}{{P}_{0}} .$$

If P₁ is very close to P₀ (P₁<2P₀), then even more integer bits may be needed. For greater resolution in the computations, one can allow the number of fractional bits used to represent the power normalizations to vary and be programmed by firmware.

For example, if P₀=−40 dBm and P₁=−20 dBm, then

$$\frac{1}{{P}_{1} {V}^{2} - {P}_{0} {V}^{2}} = 2020.202 ,$$

and log₂(2020)=10.98. Therefore, 11 integer bits and 32−11=21 fractional bits should be used to represent this power normalization. Firmware should program the following two variables in the schedule:

$$schedule \cdot P1\_minus \_P 0 \_inv \_nFracBits = 32 - ⌈ {log}_{2} ( \frac{1}{{P}_{1} - {P}_{0}} ) ⌉ = 21$$

$$schedule \cdot P1\_minus \_P 0 \_inv = round ( {2}^{schedule \cdot P 1 \_ minus \_ P 0 \_ inv \_ nFracBits} \frac{1}{{P}_{1} - {P}_{0}} )$$

P1 minus_P0_inv has now been scaled up to be represented as an integer with no fractional bits.

### Computation of DAC Values:

During the section of the schedule where a DAC is changing, its output value is computed using a piecewise linear function. An example for the first ramp up of DAC_RFIN is:

DAC_RFIN=DAC_RFIN_0+(DAC_RFIN_1−DAC_RFIN_0)*PWL_IN01((Pout−P0)*(P1_minus_P0_inv)).

Below are details on some parts of this computation.

$$Computing the product ( {P}_{out} - {P}_{x} ) * \frac{1}{{P}_{x + 1} - {P}_{x}} for x ∈ \{ 0 , 1 , … , 8 \} :$$

As stated above, schedule·Px=round(2^{P_nFracBits}(Px in Volts²)), for x∈{0, 1, . . . , 8}. Likewise,

$$schedule \cdot P1\_minus \_P 0 \_inv = round ( {2}^{schedule \cdot P 1 \_ minus \_ P 0 \_ inv \_ nFracBits} \frac{1}{{P}_{1} - {P}_{0}} ) .$$

The variables schedule·Px and schedule·Px+1_minus_Px_inv are 32 bit, all integer representations of their counterparts in Volts² and

$$\frac{1}{{Volts}^{2}} .$$

Their product is a priori a 64 bit integer:

$$( Pout - schedule \cdot Px ) * schedule \cdot Px + 1 \_minus \_Px \_inv = {2}^{{P}_{nFracBits}} ( {P}_{out} - {P}_{x} ) * {2}^{Px + 1 \_ minus \_ Px \_ inv \_ nFracBits} \frac{1}{{P}_{x + 1} - {P}_{x}} = {2}^{{P}_{nFracBits} + {P}_{x + 1} \_ minus \_ {P}_{x} \_ inv \_ nFracBits} \frac{{P}_{out} - {P}_{x}}{{P}_{x + 1} - {P}_{x}} .$$

The product

$$( {P}_{out} - {P}_{x} ) * \frac{1}{{P}_{x + 1} - {P}_{x}}$$

lies between 0 and 1. As such, one can represent it as a 32 bit integer word by multiplying by 2\hat{ }32 and rounding to the nearest integer. In other words, we would like to scale schedule·Px*schedule·Px+1_minus_Px_inv to equal

$${2}^{32} \frac{{P}_{out} - {P}_{x}}{{P}_{x + 1} - {P}_{x}} .$$

To do so, we shift down schedule·Px*schedule·Px+1_minus_Px_inv by

(P_{nFracBits}+Pₓ₊₁_minus_Pₓ_inv_nFracBits)−32,
where the difference is assumed to be >=0.

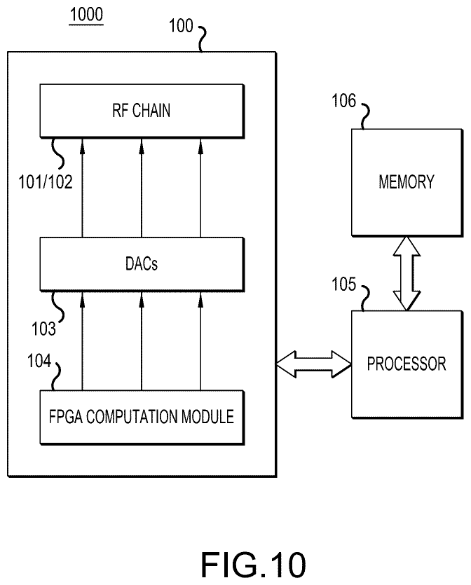

FIG. 10 is a high-level and simplified block diagram of a computing system 1000 according to embodiments of the inventive concepts.

Referring to FIG. 10, the system 1000 includes modulator gain system 100 such as that described earlier herein initially in connection with FIG. 1. As such, the modular gain system includes an FPGA computation module 104, DACs 103 and an RF chain 101/102.

The modulator gain system 100 is controlled by a processor 105 having access to one or more non-transitory computer readable storage media 106. The control by the processor 105 includes programming of the registers in the FPGA computation module 104 as described herein.

The inventive concepts encompass a non-transitory computer-readable medium 106 storing instructions that, when executed by the processor 105, cause the processor 105 to perform operations. The operations receiving a desired output power level for a plurality of cascade-connected RF modulators, determining a power region corresponding to the desired output power level from a set of predefined power regions, retrieving linearization parameters associated with the determined power region, and applying the retrieved linearization parameters to the RF modulators using a field-programmable gate array (FPGA) to achieve the desired output power level.

Examples of non-transitory computer readable media 106 include magnetic media such as hard disks, floppy disks, and magnetic tape; optical media such as compact disk-read-only memory (CD ROM) disks and digital versatile disks (DVDs) magnetooptical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described examples and embodiments, or vice versa.

While the disclosure has been particularly illustrated and described with reference to exemplary embodiments thereof, it will be appreciated by those of ordinary skill in the art that changes may be made therein without departing from the principles and spirit of the disclosure, the scope of which is defined in the appended claims and their equivalents. The exemplary embodiments should be considered in a descriptive sense only and not for purposes of limitation. Therefore, the scope of the disclosure is defined not by the detailed description of the disclosure but by the appended claims, and all differences within the scope will be construed as being included in the disclosure.

What is claimed is:

1. A system for linearizing RF modulators, comprising:
a plurality of RF modulators connected in series;
a field-programmable gate array (FPGA) configured to control the RF modulators; and
a piecewise linear mapping module implemented in the FPGA, the piecewise linear mapping module configured to:
divide an operating range of the RF modulators into multiple power regions; and
apply different linearization parameters to each power region to compensate for a non-linear behavior of the RF modulators.

2. The system of claim 1, wherein the plurality of RF modulators comprises at least three RF modulators connected in series.

3. The system of claim 2, wherein the at least three RF modulators comprise an input modulator, at least one middle modulator, and an output modulator.

4. The system of claim 3, wherein the multiple power regions comprise a lowermost power region, at least one middle power region, and a higher most power region.

5. The system of claim 4, wherein the piecewise linear mapping module is further configured to:
apply different linearization parameters to each of the input modulator, the at least one middle modulator, and the output modulator within each power region.

6. The system of claim 5, wherein the piecewise linear mapping module is further configured to:
sequence activation of the input modulator, the at least one middle modulator, and output modulator to balance noise and distortion performance across the multiple power regions, and
wherein the piecewise linear mapping module utilizes lookup tables to store the linearization parameters for each modulator in each power region.

7. The system of claim 1, comprised of a normalization process that utilizes the full bit depth piecewise linear map of a given the power range.

8. A method for linearizing RF modulators, comprising:
dividing an operating range of a plurality of series-connected RF modulators into multiple power regions;
determining linearization parameters for each power region; and
applying the linearization parameters to the RF modulators using a field-programmable gate array (FPGA) to compensate for a non-linear behavior of the RF modulators across the operating range.

9. The method of claim 8, wherein the multiple power regions comprise a lowermost power region, at least one middle power region, and a higher most power region.

10. The method of claim 9, wherein determining linearization parameters comprises:
calibrating each RF modulator individually to characterize its non-linear behavior across the operating range.

11. The method of claim 10, further comprising:
storing the linearization parameters in lookup tables implemented in the FPGA.

12. The method of claim 11, wherein applying the linearization parameters comprises:
sequencing activation of the RF modulators to balance noise and distortion performance across the multiple power regions.

13. The method of claim 12, wherein sequencing activation of the RF modulators comprises:
activating an input modulator in the low power region; then activating in succession each of at least one middle modulator in the respective at least one middle power regions; and then activating an output modulator in the high power region.

14. The method of claim 13, further comprising:
applying different linearization parameters to each of the input modulator, the at least one middle modulator, and the output modulator within each power region.

15. A non-transitory computer-readable medium storing instructions that, when executed by a processor, cause the processor to perform operations for linearizing RF modulators, the operations comprising:
receiving a desired output power level for a plurality of series-connected RF modulators;
determining a power region corresponding to the desired output power level from a set of predefined power regions;
retrieving linearization parameters associated with the determined power region; and
applying the retrieved linearization parameters to the RF modulators using a field-programmable gate array (FPGA) to achieve the desired output power level.

16. The non-transitory computer-readable medium of claim 15, wherein the operations further comprise:
calibrating each RF modulator individually to characterize its non-linear behavior across an operating range.

17. The non-transitory computer-readable medium of claim 16, wherein the operations further comprise:
storing the linearization parameters in lookup tables implemented in the FPGA.

18. The non-transitory computer-readable medium of claim 17, wherein applying the retrieved linearization parameters comprises:
sequencing activation of the RF modulators to balance noise and distortion performance across the predefined power regions.

19. The non-transitory computer-readable medium of claim 18, wherein sequencing activation of the RF modulators comprises:
activating an input modulator in a lowermost power region; then activating in succession at least one middle modulator in respective at least one middle power regions; and then activating an output modulator in a higher most power region.

20. The non-transitory computer-readable medium of claim 19, wherein the operations further comprise:
applying different linearization parameters to each of the input modulator, the at least one middle modulator, and the output modulator within each predefined power region.
